(19) United States
(12) Patent Application Publication
(10) Pub. No.: US 2015/0233989 A1
(43) Pub. Date: Aug. 20, 2015

(54) CAPACITIVE SENSING ARRAY DEVICE WITH HIGH SENSITIVITY AND HIGH FRAME RATE AND ELECTRONIC APPARATUS USING THE SAME

(71) Applicant: J-METRICS TECHNOLOGY Co., Ltd., Taipei City (TW)

(72) Inventor: Bruce C.S. CHOU, Hsin Chu (TW)

(21) Appl. No.: 14/701,233

(22) Filed: Apr. 30, 2015

Related U.S. Application Data
(63) Continuation-in-part of application No. 14/045,514, filed on Oct. 3, 2013.

(30) Foreign Application Priority Data
Oct. 12, 2012 (TW) 101137686
May 7, 2014 (TW) 103116185

(51) Int. Cl. G01R 27/26; G06F 3/041; G06F 3/044

(52) U.S. Cl. CPC G01R 27/2605; G06F 3/044; G06F 3/0416; G06F 2203/04107

(57) ABSTRACT

In a capacitive sensing array device and an electronic apparatus, a coupling signal source provides a coupling signal to an object, a constant voltage source provides a constant voltage to a shielding conductor group, and a vertical parasitic capacitor is formed between the shielding conductor group and each sensing electrode. Each sensing electrode is electrically connected to the constant voltage source via one corresponding switch module. When one sensing electrode is selected to perform sensing, the corresponding switch module is set as an open state such that the selected sensing electrode is disconnected from the constant voltage source, while the other sensing electrodes are electrically connected to the constant voltage source via their corresponding switch modules configured as short-circuit states, so that a horizontal parasitic capacitor is formed between the selected sensing electrode and the other sensing electrodes. The shielding conductor group comprises shielding conductor layers on shielding planes.

This application is a Continuation-in-Part of co-pending application Ser. No. 14/045,514, filed on Oct. 3, 2013, and claims priority of No. 103116185 filed in Taiwan R.O.C. on May 7, 2014 under 35 USC 119, the entire content of which is hereby incorporated by reference.

### BACKGROUND OF THE INVENTION

1. Field of the Invention

The invention relates to a capacitive sensing array device and an electronic apparatus using the same, and more particularly to a capacitive sensing array device with a high sensitivity and a high frame rate, and an electronic apparatus using the same.

2. Related Art

The conventional capacitive sensing technology for sensing the skin of the human body may be applied to, for example, the fingerprint sensor for sensing finger's textures or a capacitive touch panel or a capacitive touch screen.

More particularly, the basic structure of the portion of the sensor in contact with the skin's texture to sense the skin's texture is an array-type sensing member. That is, several sensing members with the same structures constitute a two-dimensional array sensor. When a finger is placed on the array sensor, for example, the ridge of the finger's texture is in direct contact with the array sensor, and the valley of the finger's texture is separated from the array sensor by a gap, so that the two-dimensional capacitive image of the finger's texture may be captured, and this is the basic principle of the capacitive skin texture sensor.

In the most frequently seen sensing member structure, due to the electroconductive property of the human body, the skin in contact with the sensor may be regarded as an equal-potential electrode plate and each sensing member may be regarded as a plate electrode, so that a capacitor is formed between each sensing member and the skin. The materials disposed between the electrode plates include the cuticle on the surface of the finger's skin and a sensor protection layer disposed on the sensing electrode and in contact with the skin. The protection layer may be a single insulating layer or may contain multiple insulating layers and must have the environment-corrosion-resistant property, the impact-resistant property, the wearing-resistant property, the electrostatic-discharge-resistant property and the like.

In order to achieve the above-mentioned properties of the protection layer, one direct method is to increase the thickness of the protection layer. However, the too-thick protection layer causes the very small sensing capacitance, thereby decreasing the sensitivity.

FIG. 1 is a schematic illustration showing an assembled structure of a conventional capacitive fingerprint sensor 500. As shown in FIG. 1, the conventional capacitive fingerprint sensor 500 is usually manufactured in two stages. In the first stage of manufacturing a fingerprint sensing chip 510, semiconductor manufacturing processes are utilized to form sensing members 514 and chip bonding pads 515 on a semiconductor substrate 511, and then a chip protection layer 512 is formed on the sensing members 514 to provide the protective and impact-resistant properties. In the second stage, which is a packaging stage, the fingerprint sensing chip 510 is placed on a package substrate 520, multiple wires 530 are bonded to the chip bonding pads 515 and package bonding pads 525 by way of wire bonding, and then a package protection layer (or referred to as a molding compound layer) 540 is provided to cover the wires 530 and the bonding pads 515 and 525, and only the region with the sensing member array is exposed. Such conventional package processes require a special mold and a special process flow to protect the sensing member region from being covered by the molding compound and need a special machine. So, the cost is high.

In the existing IC wire-bonding technology, the distance from the chip surface 513 to the package surface 523 is greater than or equal to about 100 microns (um). Taking the fingerprint sensor with the specification of 500 DPI as an example, the area of each sensing member 514 is about 50 um×50 um. If the molding compound is to deploy on the sensing member, according to the dielectric constant of the commercial molding compound, the calculated capacitance of the sensing member is smaller than about 1 fF, which is too small to design a sensing circuit. If the thickness control of the package substrate, the thickness control of the chip and the like are considered at the same time, this distance further causes the great sensing error.

Thus, the conventional package protection layer 540 cannot be disposed above and cannot cover the sensing member 514. So, the chip protection layer 512 has to be formed in the first stage, and the thickness (about 1 to 20 microns) of the chip protection layer 512 cannot be too thick to affect the sensing capacitance. Consequently, in addition to the high cost, it is a great challenge to the requirements on the environment-corrosion-resistant property, the impact-resistant property, the wearing-resistant property, the electrostatic-discharge-resistant property and the like of the sensor.

FIG. 2 is a schematic illustration partially showing sensing electrodes of a conventional capacitive fingerprint sensor 600. As shown in FIG. 2, in addition to the sensing capacitor Cf between each sensing electrode 610 of the capacitive fingerprint sensor 600 and the finger F, a parasitic capacitor Cp1 is present when viewed from the sensing electrode 610 to the inside of the chip. In addition, because the sensor device is an array device having a plurality of sensing members, a parasitic capacitor Cp2 is also present between each of the sensing electrodes 610 and each of its neighboring sensing electrodes 610. These parasitic capacitors are in the fluctuating states. This non-constant parasitic capacitor interferes with the measurement, and is one of the main reasons of the incapability of achieving the high sensitivity. In order to achieve the sensitivity of Cf smaller than 1 fF, the solution of the interference between Cp1 and Cp2 is the most important issue.

### SUMMARY OF THE INVENTION

It is therefore an object of the invention to provide a capacitive sensing array device with a high sensitivity and a high frame rate, and an electronic apparatus using the same, in which the influence of the parasitic capacitor can be eliminated, and the high sensitivity property can be provided when the thick protection layer is present.

To achieve the above-identified object, the invention provides a capacitive sensing array device comprising sensing electrodes, a shielding conductor group, a coupling signal source, a constant voltage source and multiple switch modules. The sensing electrodes are separately arranged in an array. A sensing capacitor is formed between the sensing electrode and an object. The shielding conductor group is disposed below the sensing electrodes. The coupling signal source provides a coupling signal coupled to the object. The constant voltage source provides a constant voltage to the shielding conductor group, so that a stable vertical parasitic capacitor is formed between the shielding conductor group and each of the sensing electrodes. The switch modules are electrically connected to the sensing electrode and the constant voltage source in a one-to-one manner. When one of the sensing electrodes is selected to perform sensing, the switch modules are configured such that the selected sensing electrode is disconnected from the constant voltage source, while the other sensing electrodes is electrically connected to the constant voltage source, so that a stable horizontal parasitic capacitor is formed between the selected sensing electrode and the other sensing electrodes. The shielding conductor group comprises multiple shielding conductor layers disposed on multiple shielding planes.

The invention further provides a capacitive sensing array device with a high frame rate. The capacitive sensing array device comprises multiple sensing electrodes, a function block group, a coupling signal source, a constant voltage source and multiple switch modules. The sensing electrodes are separately arranged in an array. A sensing capacitor is formed between each of the sensing electrodes and an object. The function block group is disposed below the sensing electrodes. The function block group comprises multiple function blocks each comprising a wire layer. The wire layers are disposed on multiple planes. The coupling signal source provides a coupling signal coupled to the object. The constant voltage source provides a constant voltage to each of the wire layers so that a stable vertical parasitic capacitor is formed between the function block group and each of the sensing electrodes. The switch modules are electrically connected to the sensing electrode and the constant voltage source in a one-to-one manner. When one of the sensing electrodes is selected to perform sensing, the switch modules are configured such that the selected sensing electrode is disconnected from the constant voltage source, and the other sensing electrodes are electrically connected to the constant voltage source, so that a stable horizontal parasitic capacitor is formed between the selected sensing electrode and the other sensing electrodes.

The invention further provides an electronic apparatus comprising a body, a display, the above-mentioned capacitive sensing array device, a housing and a processor. The display mounted on the body displays a frame. The capacitive sensing array device is mounted on the body. The housing is mounted on the body and covers the display and the capacitive sensing array device. The capacitive sensing array device senses a pattern of the object via the housing. The processor, electrically connected to the capacitive sensing array device and the display, processes the pattern of the object and interacts with a user through the display.

With the design of the capacitive sensing array device of the invention, even if the finger is separated from the capacitive sensing array device by the protection layer and the housing, the high sensitivity still can be obtained, the sensing result cannot be affected by the parasitic capacitor, and the high frame rate is further obtained. That is, the frame rate of the capacitive sensing array device is increased, so that the fingerprint sensing speed is increased, and the performance of the electronic apparatus installed with the capacitive sensing array device is enhanced.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic illustration showing a structure of a conventional capacitive fingerprint sensor.

FIG. 2 is a schematic illustration partially showing sensing electrodes of a conventional capacitive fingerprint sensor.

FIG. 3 is a schematic illustration showing a structure of a capacitive sensing array device according to a first embodiment of the invention.

FIG. 4 is a schematic illustration partially showing a structure design of sensing electrodes of the capacitive sensing array device according to the first embodiment of the invention.

FIG. 5 is a schematic illustration showing a single sensing member and its corresponding sensing circuit of the capacitive sensing array device according to the first embodiment of the invention.

FIG. 6A is a schematic view showing a structure design of a partial sensing electrode of the capacitive sensing array device with the low parasitic capacitance and the high sensitivity according to a second embodiment of the invention.

FIGS. 6B and 6C are schematic views showing a structure design of a partial sensing electrode of a capacitive sensing array device according to a third embodiment of the invention.

FIG. 7 is a schematic view showing an electronic apparatus according to the embodiment of the invention.

FIG. 8 is a cross-sectional view taken along a line 9-9 of FIG. 7.

### DETAILED DESCRIPTION OF THE INVENTION

The present invention will be apparent from the following detailed description, which proceeds with reference to the accompanying drawings, wherein the same references relate to the same elements.

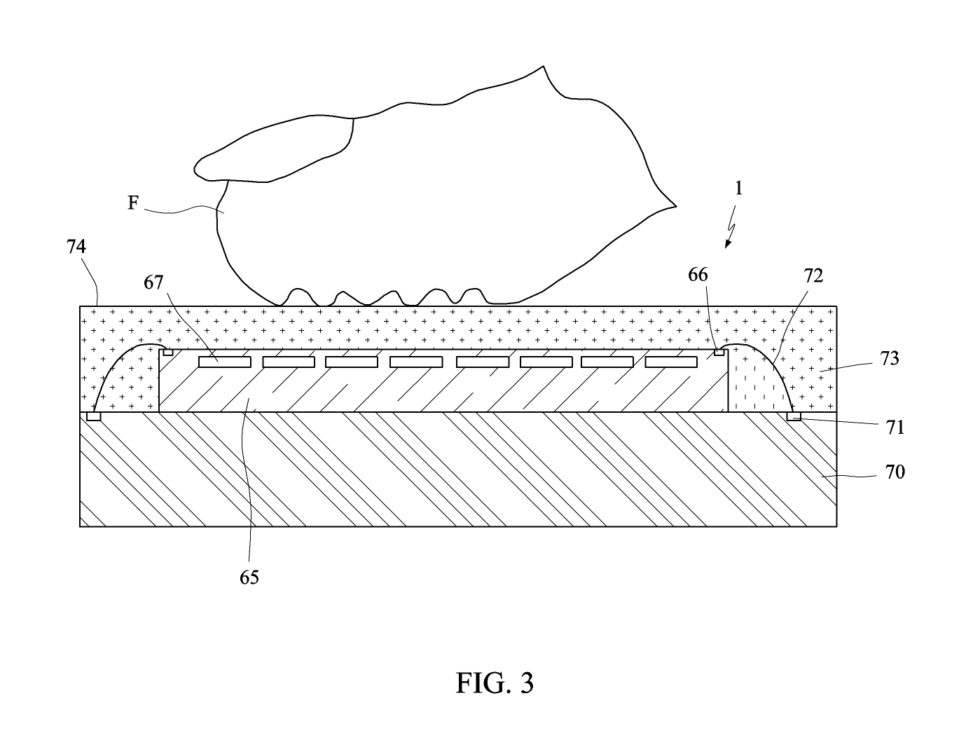

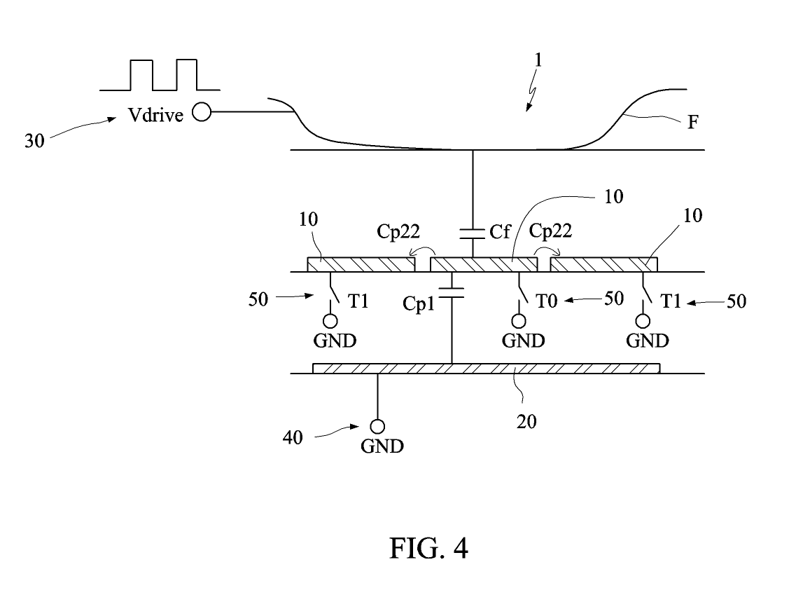

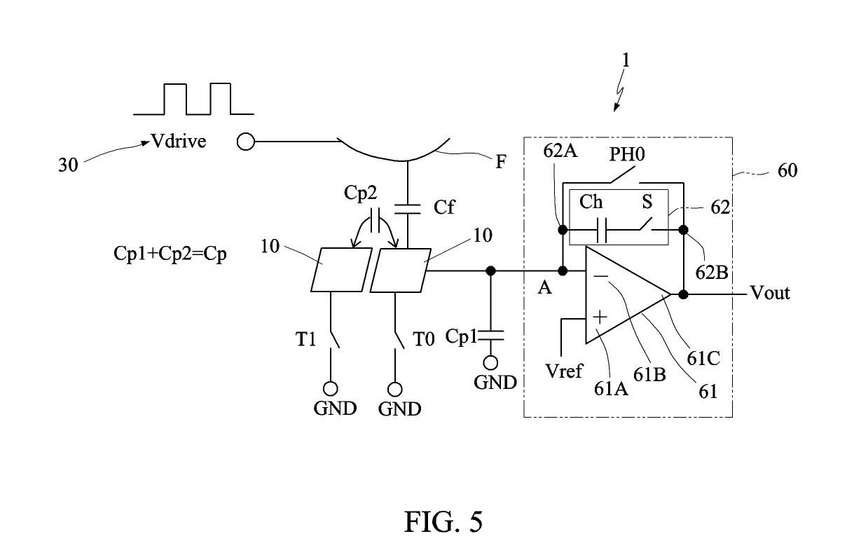

FIG. 3 is a schematic illustration showing a structure of a capacitive sensing array device 1 according to a first embodiment of the invention. FIG. 4 is a schematic illustration partially showing a structure design of sensing electrodes of the capacitive sensing array device 1 according to the first embodiment of the invention. FIG. 5 is a schematic illustration showing a single sensing member and its corresponding sensing circuit of the capacitive sensing array device 1 according to the first embodiment of the invention. Referring to FIGS. 3 to 5, the capacitive sensing array device 1 of this embodiment includes sensing electrodes 10, a shielding conductor layer 20, a coupling signal source 30, a constant voltage source 40, switch modules 50, a semiconductor substrate 65, a package substrate 70, wires 72 and a package protection layer 73.

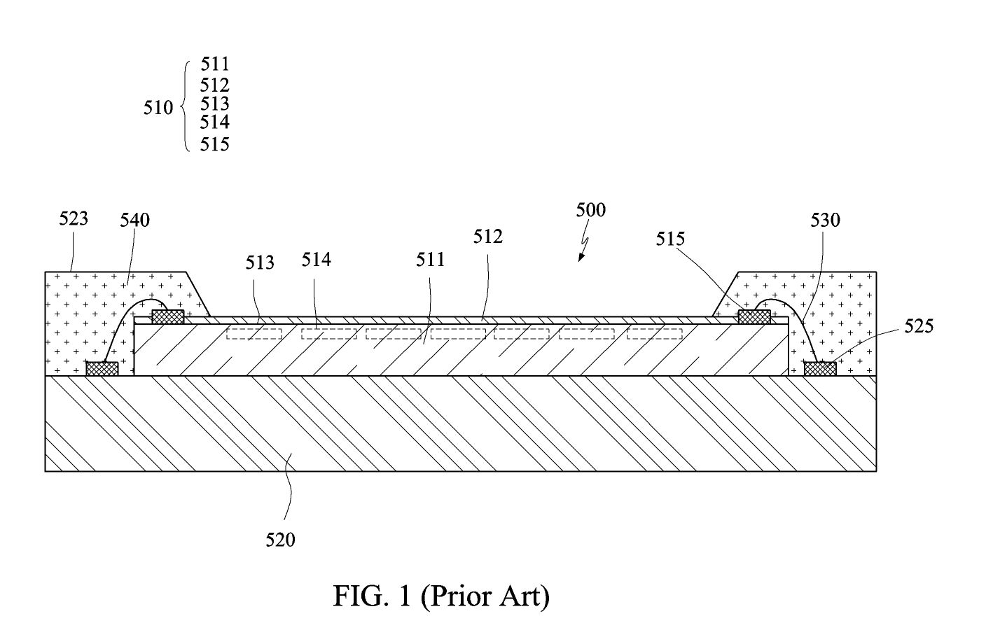

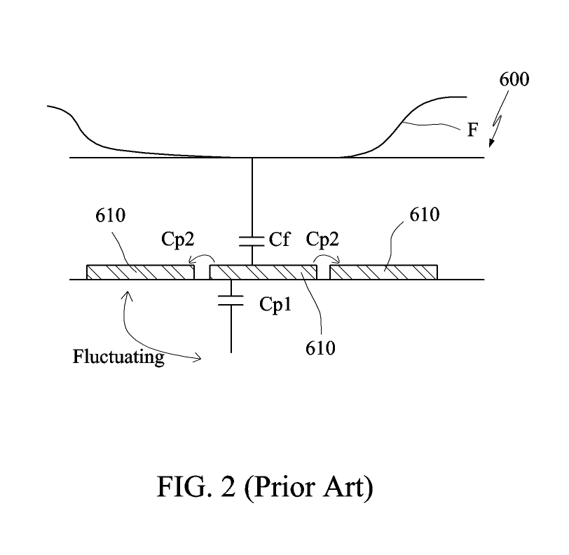

The sensing electrodes 10, the shielding conductor layer 20, the coupling signal source 30, the constant voltage source 40 and the switch modules 50 may constitute a portion of a sensing member 67 or the whole sensing member, and are formed in the semiconductor substrate 65. Herein, the manufacturing processes applied to the semiconductor substrate include complete front-end and post-end semiconductor manufacturing processes, such as the transistor device manufacturing processes and the wire connecting processes. In this embodiment, these structures are manufactured using, for example, but without limitation to, semiconductor manufacturing processes (e.g., CMOS processes), so that the manufacturing cost is significantly decreased. The semiconductor substrate 65 is disposed on the package substrate 70. Multiple first bonding pads 71 on the package substrate 70 may be electrically connected to multiple second bonding pads 66 on the semiconductor substrate 65 through the wires 72 by way of wire bonding to provide the input/output interface for the signal and the power of the package product. The package protection layer 73 is implemented using a molding compound, typically used in the package, to cover the semiconductor substrate 65, the wires 72, the first bonding pads 71 and the second bonding pads 66. In one example, the material of the package protection layer 73 includes the epoxy resin serving as the molding compound (molding compound), and the package protection layer 73 has the thickness greater than or equal to 100 um, and the hardness greater than 5H, so that the wearing-resistant property, the electrostatic-discharge-resistant property, the impact-resistant property and the like may be provided. In addition, the package protection layer 73 has an exposed surface 74 in contact with an object F, wherein the exposed surface 74 is a flat surface, and the overall exposed surface 74 serves as a complete upper flat surface of the capacitive sensing array device 1 without the concave surface of FIG. 1. Thus, the requirements of the full flat surface device can be satisfied.

Regarding the detailed structure of the sensing member 67, these sensing electrodes 10 are separately arranged in an array including, without limitation to, a one-dimensional array or a two-dimensional array. Each sensing electrode 10 and the object F form a sensing capacitor Cf. In this example, the object is a finger. However, the invention is not restricted thereto. Any device operating according to the capacitive sensing principle may be used as the sensing array device of the invention.

The shielding conductor layer 20 is disposed below the sensing electrodes 10. The shielding conductor layer 20 and each sensing electrode 10 form a vertical parasitic capacitor Cp1. The shielding conductor layer 20 may be a piece of conductor layer, may also be multiple conductor layers, and may correspond to the sensing electrodes 10 in a one-to-one, one-to-many or many-to-one manner so as to provide the constant parasitic capacitor. This independently designed shielding conductor layer does not pertain to one portion of the sensing circuit, and the main object of the shielding conductor layer is to shield the sensing electrode disposed above the shielding conductor layer from seeing the sensing circuit (e.g., the circuit shown in FIG. 5) inside the substrate. Consequently, the sensing electrode is not affected by the potential at the bottom, so that the charge distribution is not changed, and the signal stability of the sensing electrode is not affected.

In FIG. 4, the middle sensing electrode 10 and its surrounding members also form a horizontal parasitic capacitor Cp22. These horizontal parasitic capacitors Cp22 are equivalent to a horizontal parasitic capacitor Cp2 in FIG. 5. Thus, the sensing electrode 10 and its neighboring sensing electrodes 10 form the horizontal parasitic capacitor Cp2.

The shielding conductor layer 20 and the sensing electrodes 10 may be formed using the metal manufacturing process of the semiconductor manufacturing processes. The material between the shielding conductor layer 20 and the sensing electrodes 10 may contain a single-layer or multiple inter-metal dielectrics (IMD) layers. The sensing members may be formed using multiple metal and IMD manufacturing processes of the semiconductor manufacturing processes.

The coupling signal source 30 is coupled to the object F and provides a coupling signal Vdrive coupled to the object F. The coupling signal Vdrive may be directly or indirectly coupled to the object F, wherein the direct coupling may transfer the coupling signal to the object F using a conductor in contact with the object F, and the indirect coupling may be implemented by disposing a dielectric layer between the conductor and the object F. Since the direct coupling and the indirect coupling are well known in the art, detailed descriptions and restrictions thereof will be omitted.

The constant voltage source 40 provides a constant voltage to the shielding conductor layer 20 so that a stable vertical parasitic capacitor Cp1 is formed between the shielding conductor layer 20 and each sensing electrode 10. In this embodiment, the grounding voltage (GND) of 0V serves as the constant voltage. However, the invention is not restricted thereto, the constant voltage may also be equal to 3.3V, 5V or the like to achieve the effect of the invention. However, it is to be noted that the constant voltage source must provide the very stable voltage, which cannot fluctuate under the external interference. This is because the fluctuating voltage would decrease the sensitivity of the sensing member.

These switch modules 50 are only represented by T0 and T1 in FIGS. 4 and 5, and these switch modules 50 are electrically connected to the constant voltage source and these sensing electrodes 10 in a one-to-one manner. When one sensing electrode 10 is selected to perform the sensing, the switch modules 50 are configured such that an open-circuited state is formed between the sensing electrode 10 and the constant voltage source 40, while the short-circuited state is formed between the other sensing electrodes 10 and the constant voltage source 40, so that a stable horizontal parasitic capacitor Cp2 is formed between the selected sensing electrode 10 and the other sensing electrodes 10, and that the output of the capacitive sensing array device 1 does not relate to the horizontal parasitic capacitor Cp2 and the vertical parasitic capacitor Cp1 (see the following derivation). The switch module 50 may be implemented by, for example but without limitation to, a transistor or any other suitable means. In FIGS. 4 and 5, when the middle sensing electrode 10 is selected to perform the sensing, the switch module T0 is in the open-circuited state, and the switch module T1 is in the short-circuited state (i.e., turned-on state). Consequently, the surrounding sensing electrodes 10 are grounded (or coupled to the constant voltage), while the bottom shielding conductor layer 20 is set as the grounded state (or coupled to the constant voltage). As a result, a stable shielding environment may be provided to completely surround the sensing electrode therein. Although a relatively large parasitic capacitor is still present between the sensing electrode and the neighboring shielding environment, this parasitic capacitor is different from the conventional design and has a constant and stable capacitance value. This is advantageous to the design of the sensing circuit, and is also a key point of the invention.

As shown in FIG. 5, the capacitive sensing array device 1 may further include reading circuits 60, which are electrically connected to the sensing electrodes 10 and output multiple output signals Vout, respectively. In this embodiment, in order to prevent the signal of each sensing electrode from being transmitted too far and interfered, each sensing member is configured to be connected to an operational amplifier for amplifying the sensing signal on site. Thus, the invention is free from the interference caused by the too-long transmission line (array device's usual issue). Therefore, each reading circuit 60 includes an operational amplifier 61, a tunable capacitor 62 and a reset switch PH0.

All or a portion of the operational amplifier 61 may be formed under the sensing electrode 10, and one sensing electrode 10 may correspond to one operational amplifier 61. Of course, multiple sensing electrodes 10 may also correspond to one operational amplifier 61. The operational amplifier 61 has a positive input terminal 61A, a negative input terminal 61B and an output terminal 61C. The negative input terminal 61B is electrically connected to the sensing electrode 10, and the positive input terminal 61A is electrically connected to a reference voltage Vref. The tunable capacitor 62 has a first terminal 62A electrically connected to the negative input terminal 61B, and a second terminal 62B electrically connected to the output terminal 61C. In this example, the tunable capacitor 62 is constituted by a capacitor Ch and a switch S. In this example, because only one capacitor Ch is provided, the switch S may be removed. The reset switch PH0 and the tunable capacitor 62 are connected in parallel.

According to the circuit diagram of FIG. 5, the output signal Vout may be derived according to the electrical charge conservation principle.

When Vdrive=0, the reset switch PH0 is in the short-circuited state, and the charge Q1 at the node A may be represented by:

Q1=Cf×(Vref−Vdrive)+Cp×Vref=Cf×Vref+Cp×Vref.

When Vdrive is high, the reset switch PH0 is in the open-circuited state, and the charge Q2 at the node A may be represented by:

Q2=Cf×(Vref−Vdrive)+Cp×Vref+Ch×(Vref−Vout).

According to the electrical charge conservation principle, Q1=Q2 may be obtained.

That is,

Cf×Vref+Cp×Vref=Cf×Vref−Cf×Vdrive+Cp×Vref+Ch×Vref−Ch×Vout.

The expression may be simplified as:

Cf×Vdrive−Ch×Vref=−Ch×Vout.

Then, it is obtained:

i Vout=Vref−(Cf/Ch)×Vdrive,

wherein Cp=Cp1+Cp2. According to the above-mentioned equation, it is found that the output signal Vout does not relate to the parasitic capacitors Cp1 and Cp2. As mentioned hereinabove, the feature of the invention is to stabilize the fluctuating value of the parasitic capacitor, which fluctuates due to the uncontrolled surrounding environment, so that the parasitic capacitor may be naturally neglected under the operation principle of the operational amplifier sensing circuit. In addition, Cf/Ch is a gain. In the practical design, Ch is as small as possible because the sensing signal may be amplified in each independent sensing member so that the sensing signal cannot be interfered in the transmission line to affect the signal quality. In one embodiment of the invention, Vdrive is equal to 3.3V, Vref is equal to 1.8V, and Ch ranges from 1 to 4 fF. However, the invention is not particularly restricted thereto.

It is worth noting that the sensing principle derived hereinabove is based on the static electromagnetic theory. If the dynamic (transient) condition is considered, then the Cp does not affect the output of Vout. If the RC delay is considered, then the too large parasitic capacitor Cp requires the longer time to charge the sensing electrode 10 (the seen total capacitance of the sensing capacitor and the parasitic capacitor) to reach the predetermined voltage, as well as the longer discharge time. This is disadvantageous to the sweep-type fingerprint sensing chip because the sweep-type fingerprint sensor needs to capture more the fragment fingerprint images (the fragment images correspond to the size of the sensing member matrix of the sweep-type sensing chip) per unit time in order to achieve the better image stitching effect, and the larger parasitic capacitance affects the number of frames or images captured. To extend the above-mentioned contents of the high sensitivity fingerprint sensing chip, the structure design capable of enhancing the frame rate without affecting the sensitivity will be described in the following.

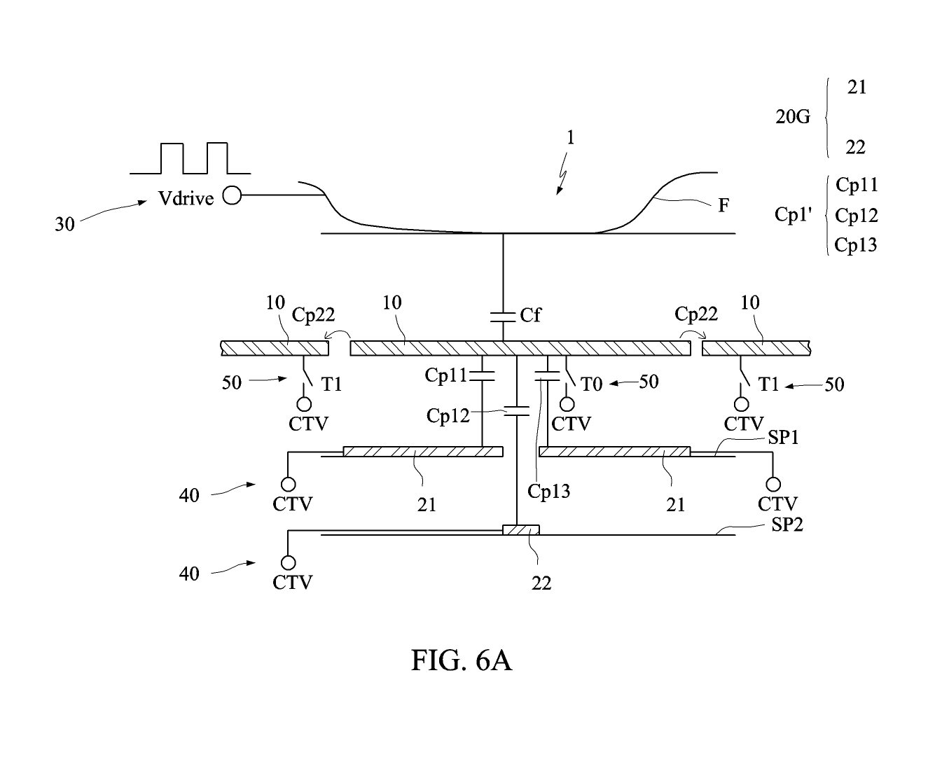

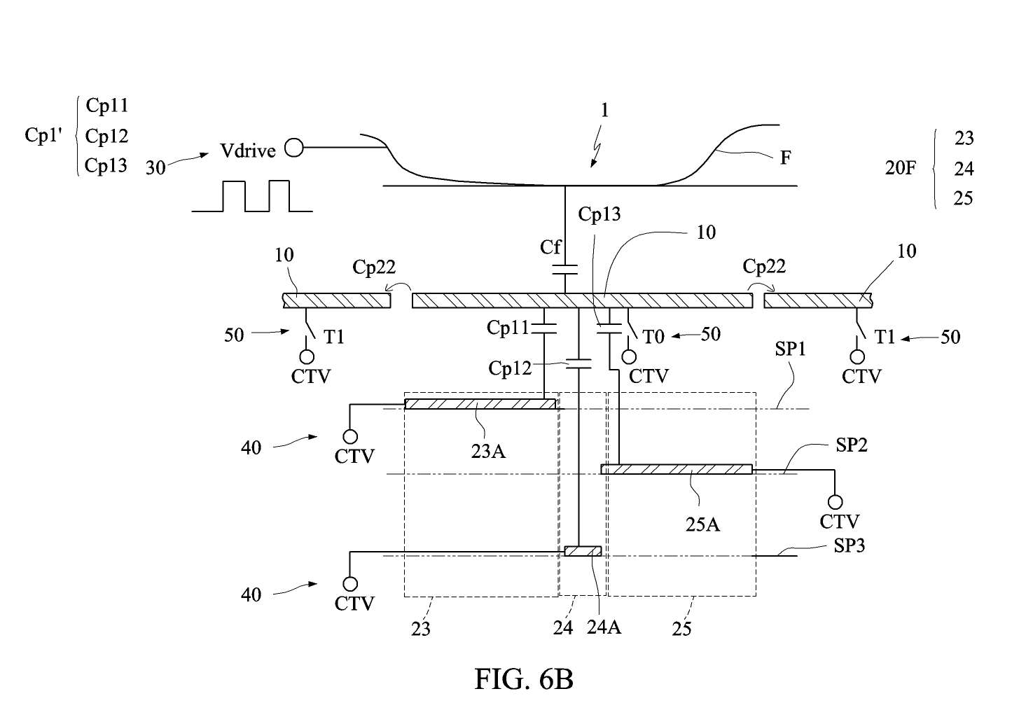

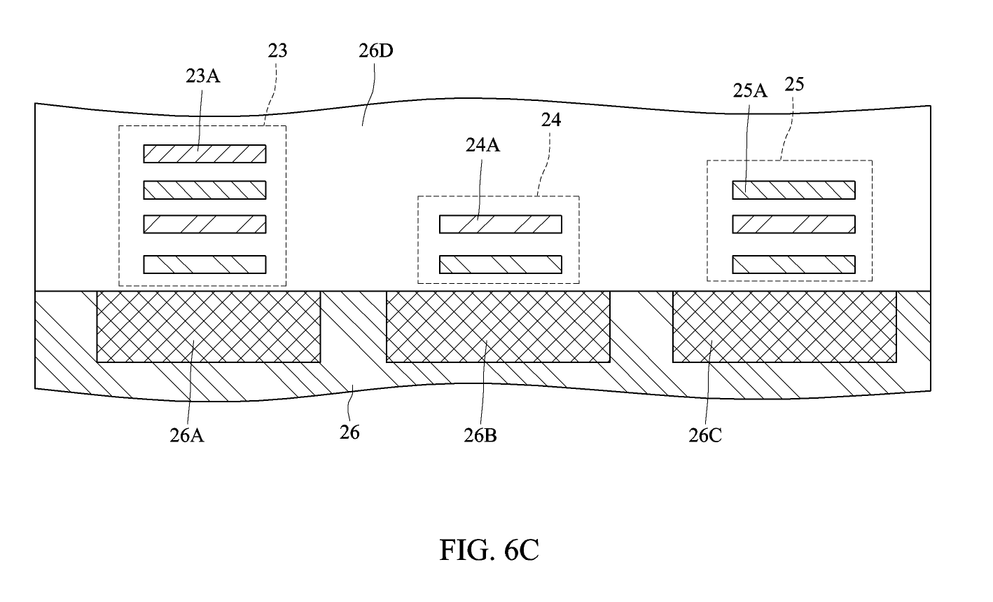

FIG. 6A is a schematic view showing a structure design of a partial sensing electrode of the capacitive sensing array device with the low parasitic capacitance and the high sensitivity according to a second embodiment of the invention. It is worth noting that the schematic view of the structure of the capacitive sensing array device of this embodiment is also shown in FIG. 3. Referring to FIGS. 6A and 3, the capacitive sensing array device 1 of this embodiment comprises multiple sensing electrodes 10, a shielding conductor group 20G, a coupling signal source 30, a constant voltage source 40, multiple switch modules 50, a semiconductor substrate 65, a package substrate 70, multiple wires 72 and a package protection layer 73. According to the analysis, if the parasitic capacitance can be effectively decreased, then the charge/discharge time can be effectively shortened, so that the frame rate can be increased. Thus, this embodiment extends from the previous embodiment and adopts the shielding conductor group 20G to replace the shielding conductor layer 20. That is, the shielding conductor group 20G comprises at least two shielding conductor layers 21 and 22, which are disposed on different shielding planes SP1 and SP2. The shielding conductor group 20G is also formed in the semiconductor substrate 65. Thus, the sensing electrodes 10 are separately arranged in an array. Each sensing electrode 10 and the object F form the sensing capacitor Cf. The shielding conductor group 20G is disposed below the sensing electrodes 10. According to the structure depicted in FIG. 6A, the shielding conductor group 20G is disposed under the middle sensing electrode 10. The coupling signal source 30 provides the coupling signal Vdrive coupled to the object F. The constant voltage source 40 provides a constant voltage CTV to the shielding conductor group 20G. Thus, a stable vertical parasitic capacitor Cp1′ (having the capacitance equal to that of the equivalent capacitor of the parasitic capacitors Cp11, Cp12 and Cp13) is formed between the shielding conductor group 20G and each sensing electrode 10. The multiple switch modules 50 are electrically connected to the sensing electrodes 10 and the constant voltage source 40 in a one-to-one manner. When one of the sensing electrodes 10 is selected to perform sensing, the switch modules 50 are configured such that the selected sensing electrode 10 is disconnected from the constant voltage source 40, while the other sensing electrodes 10 are electrically connected to the constant voltage source 40, such that a stable horizontal parasitic capacitor Cp2 is formed between the selected sensing electrode 10 and the other sensing electrodes 10. The shielding conductor group 20G comprises multiple shielding conductor layers 21 and 22, which are disposed on multiple shielding planes SP1 and SP2, respectively. The shielding conductor group 20G is formed in the semiconductor substrate, and the shielding conductor layers 21 and 22 are conductors (e.g., metal) formed on different planes and in different processes. In addition, one portion (especially the shielding conductor layer 22) of the shielding conductor layers 21 and 22 may pertain to an integrated circuit block or multiple integrated circuit blocks (the integrated circuit block will be described later). In addition, the shielding conductor layers on different shielding planes are electrically connected together so as to provide a stable parasitic potential. For example, the shielding conductor layers are connected to the constant voltage CTV or the common ground potential (GND), and this is very usual in the circuit design.

In this embodiment, when the shielding conductor layers 21 and 22 are projected onto one shielding plane SP1/SP2, multiple projection regions are formed, and the neighboring projection regions may overlap with each other, or may not overlap with each other. That is, the coverage areas of the shielding conductor layers 21 and 22 in the horizontal direction are complementary. In another example, the coverage area of the shielding conductor layers 21 and 22 in the horizontal direction has a notch. In still another example, the coverage area of the shielding conductor layers 21 and 22 in the horizontal direction has the overlapped portion. That is, the neighboring projection regions partially overlap with each other. It is worth noting that although two shielding planes SP1 and SP2 are described in FIG. 6A, the number of the shielding planes may be two, three or more than three.

Consequently, the equivalent parasitic capacitor Cp1′ of the parasitic capacitors Cp11, Cp12 and Cp13 of the second embodiment is smaller than the parasitic capacitor Cp1 of the first embodiment. Because the charge and discharge speeds of the smaller capacitor are faster, the charge and discharge times of the capacitor of the second embodiment are shortened, so that the frame rate of the capacitive sensing array device is increased, and the fingerprint sensing speed is increased, thereby enhancing the performance of the electronic apparatus installed with the capacitive sensing array device. According to another point of view, the shielding conductor layer 21 pertains to the layout design of the dedicated conductor layer (similar to the design of FIG. 4), and the shielding conductor layer 22 may pertain to one portion of an integrated circuit block. That is, a portion of the shielding conductor layer comes from the integrated circuit block. In the first embodiment, the shielding conductor group shields the sensing electrode so that the integrated circuit cannot be affected by the sensing electrode disposed hereinabove. Therefore, in the second embodiment, the shielding conductor layer shields the integrated circuit disposed hereinbelow, so that the sensing electrode is not affected by the integrated circuit disposed hereinbelow. The overall shielding conductor group can shield the sensing electrode from the integrated circuit.

FIGS. 6B and 6C are schematic views showing a structure design of a partial sensing electrode of a capacitive sensing array device 1 according to a third embodiment of the invention. As shown in FIGS. 6B and 6C, the structure of this embodiment is partially similar to the first embodiment except that no physical design of the shielding layer (capable of significantly reducing the parasitic capacitance) is present in this embodiment, but the design advantages the same as that of the shielding layer (providing a stable parasitic capacitor) still can be obtained. This is named as the design of the virtual shielding layer. Thus, the capacitive sensing array device 1 of this embodiment comprises sensing electrodes 10, a function block group 20F, a coupling signal source 30, a constant voltage source 40 and multiple switch modules 50.

The sensing electrodes 10 are separately arranged in an array, and each sensing electrode 10 and the object F from the sensing capacitor Cf. The function block group 20F is disposed below the sensing electrodes 10. The coupling signal source 30 provides a coupling signal Vdrive coupled to the object F.

The multiple switch modules 50 are electrically connected to the sensing electrodes 10 and the constant voltage source 40 in a one-to-one manner. When one of the sensing electrodes 10 is selected to perform sensing, the switch modules 50 are configured such that the selected sensing electrode 10 is disconnected from the constant voltage source 40, while the other sensing electrodes 10 are electrically connected to the constant voltage source 40. Thus, a stable horizontal parasitic capacitor Cp22 is formed between the selected sensing electrode 10 and the other sensing electrodes 10.

In the design of the invention, each sensing member corresponds to the sensing electrode, and one sensing circuit (the complete portion or the partial portion of at least one operational amplifier 61 of FIG. 5 in this embodiment), wherein the sensing circuits are completely the same. In order to describe the inventive step and novelty of this embodiment, only the function block 23/24/25 represents the sensing circuit, so that those skilled in the art may understand and implement this. The function blocks 23, 24 and 25 are disposed below the single sensing electrode, and are disposed above active blocks 26A, 26B and 26C of a substrate 26, respectively, wherein each active block 26A/26B/26C provides an electric function (e.g., the complete or partial function of the sensing circuit) in conjunction with each function block 24/25/26. The active block 26A/26B/26C is the so-called active semiconductor element having the function of a NMOS or PMOS transistor formed in the CMOS manufacturing process, for example. Therefore, the complete function of each function block further comprises the function of the active block. However, each active block 26A/26B/26C does not inevitably contain the active element.

Thus, the function block 23/24/25 in one example may be formed by combing a post-stage metal layer with an inter-metal dielectric layer (the so-called wiring structure) formed in the CMOS manufacturing process in order to connect the active device of the active block to form an integrated circuit block. That is, the complete or partial portion of the shielding conductor layer comes from an integrated circuit block, or one portion of the shielding conductor layer pertains to one portion of a function block containing the passive component. Of course, the function block 23/24/25 in another example may further comprise a capacitor, an inductor or a resistor frequently used in the analog circuit. For example, the combination of 26A and 23 may be a first integrated circuit block of the input terminal of the operational amplifier, the combination of 26B and 24 may be a second integrated circuit block of the output terminal of the operational amplifier, and the combination of 26C and 25 may be a third integrated circuit block of the reset switch PH0 combined with the tunable capacitor 62 (FIG. 5). These integrated circuit blocks are connected together to form the sensing circuit corresponding to each sensing electrode. That is, the partial or complete portion of the shielding conductor layer comes from multiple or all integrated circuit blocks. In other words, the function block and the active block constitute an integrated circuit block, which is the complete or portion of an operational amplifier (may a transistor). It is worth noting that the function block 23/24/25 is only used to describe the inventive step and the novelty of the invention, and the number or functions of the associated function blocks are not particularly restricted.

The significant characteristic of this embodiment is that the function blocks 23, 24 and 25 (constituting the function block group 20F) and the outermost wire layer 23A/24A/25A are configured to be connected to the constant voltage source 40 when the first, second and third integrated circuit blocks are designed, so that the electrical connections to the corresponding integrated circuit blocks are provided. This also provides a shielding effect to the corresponding integrated circuit blocks (i.e., to shield one or multiple integrated circuit blocks) to prevent each operating integrated circuit block from interfering with the sensing electrode disposed above the integrated circuit block. This can achieve the shielding effect the same as FIG. 4 but is still a completely different design idea because the original object of shielding the sensing electrode is changed to the object of shielding the bottom integrated circuit block, and the wire layer 23A/24A/25A is originally one portion of each integrated circuit block, and is not an independent shielding layer of FIG. 4 (additional one metal process is added, and the manufacturing cost is increased). Most important of all, the wire layers 23A, 24A and 25A are disposed on multiple planes SP1, SP2 and SP3, respectively, and connected to a constant voltage source 40, which provides a constant voltage CTV (e.g., 3.3V, 5V or other constant voltages comprising the ground potential) to the wire layers 23A, 24A and 25A. Thus, a stable vertical parasitic capacitor Cp1′, having the capacitance equal to that of the equivalent capacitor of the parasitic capacitors Cp11, Cp12 and Cp13 is formed between the function block group 20F and each sensing electrode 10. The good design can significantly decrease the capacitance of Cp1′, and thus achieve the object of the invention.

It is worth noting that there may be wire layers disposed under the wire layers 23A, 24A and 25A. In another example, however, no wire layer is disposed under the wire layers 23A, 24A and 25A. One or multiple dielectric layers 26D may be present between the wire layers 23A, 24A and 25A. Consequently, it is possible to utilize the semiconductor manufacturing process to form the wire layers 23A, 24A and 25A on different planes to achieve the object of the embodiment of the invention.

Therefore, the integrated circuit block is composed of a function block and one or multiple active blocks. In one embodiment, the function block is the wire, and the active block is the element, wherein the wire and element constitute the complete integrated circuit block. Furthermore, it is worth noting that the shielding conductor layer of the first embodiment is used to shield the sensing electrode, while the shielding conductor layers of the second and third embodiments of the invention are used to shield the integrated circuit or integrated circuit block. In the second embodiment, one portion (shielding conductor layer 21) pertains to the dedicated independent shielding conductor layer, and the other portion (shielding conductor layer 22) is not the dedicated shielding conductor layer because the shielding conductor layer 22 is designed into each integrated circuit block. In the second embodiment, each of the wire layers 23A, 24A and 25A is not the dedicated shielding conductor layer and is designed into each the integrated circuit block and becomes one portion of the function block (i.e., one portion of the wire). In addition, the wire layers 23A, 24A and 25A are used to shield the lower integrated circuit so that the sensing electrode is not affected by the lower integrated circuit, and the wire layers 23A, 24A and 25A can shield the sensing electrode from the integrated circuit.

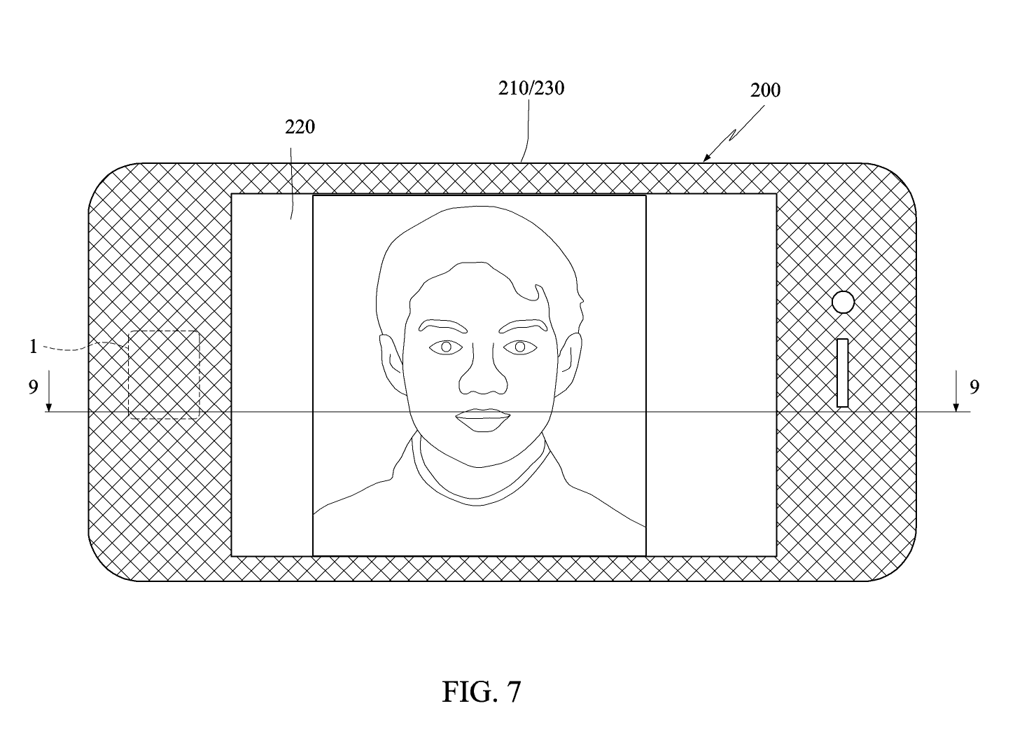

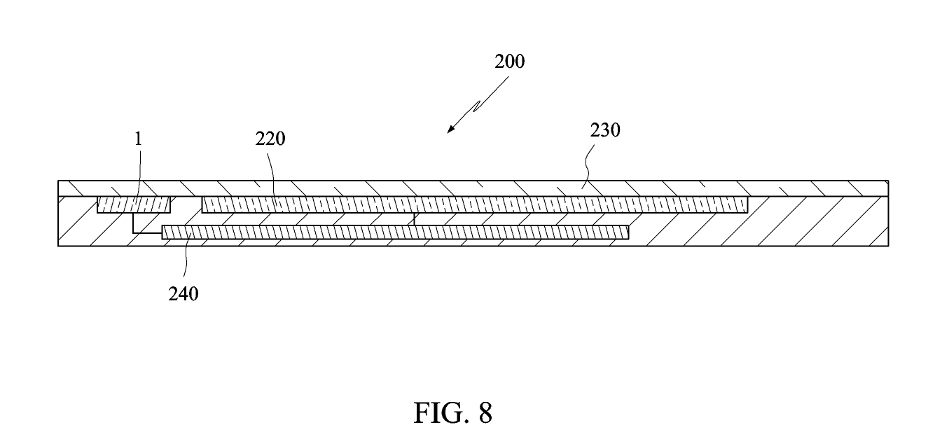

FIG. 7 is a schematic view showing an electronic apparatus 200 according to the embodiment of the invention. FIG. 8 is a cross-sectional view taken along a line 9-9 of FIG. 7. Referring to FIGS. 7 and 8, the electronic apparatus 200 of the invention comprises a body 210, a display 220, a capacitive sensing array device 1, a housing 230 and a processor 240. The display 220 mounted on the body 210 displays a frame. The capacitive sensing array device 1 is mounted on the body 210. The housing 230 is mounted on the body 210 and covers the display 220 and the capacitive sensing array device 1. The capacitive sensing array device 1 senses the pattern of the object F via the housing 230. The processor 240, electrically connected to the capacitive sensing array device 1 and the display 220, processes the pattern of the object F and interacts with a user through the display 220. The housing 230 may be transparent or opaque, and may also be, for example but without limitation to, an upper cover, a lower cover or a side cover of the electronic apparatus.

In another example, the capacitive sensing array device may be exposed to the outside and functions as the main button and the arrow button of the electronic apparatus to facilitate the user in recognizing the button region. Thus, in addition to the provision of the function of sensing the object, the capacitive sensing array device may further provide the button function, so that the user can input a control instruction including, for example but without limitation to, the selecting instruction, the moving instruction or the like.

With the design of the capacitive sensing array device of the invention, even if the finger is separated from the capacitive sensing array device by the protection layer and the housing, the high sensitivity still can be obtained, the sensing result cannot be affected by the parasitic capacitor, and the high frame rate is further obtained. That is, the frame rate of the capacitive sensing array device is increased, so that the fingerprint sensing speed is increased, and the performance of the electronic apparatus installed with the capacitive sensing array device is enhanced.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. A capacitive sensing array device, comprising:
sensing electrodes separately arranged in an array, wherein a sensing capacitor is formed between the sensing electrode and an object;
a shielding conductor group disposed below the sensing electrodes;
a coupling signal source providing a coupling signal coupled to the object;
a constant voltage source providing a constant voltage to the shielding conductor group, so that a stable vertical parasitic capacitor is formed between the shielding conductor group and each of the sensing electrodes; and
multiple switch modules electrically connected to the sensing electrode and the constant voltage source in a one-to-one manner, wherein when one of the sensing electrodes is selected to perform sensing, the switch modules are configured such that the selected sensing electrode is disconnected from the constant voltage source, while the other sensing electrodes are electrically connected to the constant voltage source, so that a stable horizontal parasitic capacitor is formed between the selected sensing electrode and the other sensing electrodes, wherein the shielding conductor group comprises multiple shielding conductor layers disposed on multiple shielding planes.

2. The capacitive sensing array device according to claim 1, further comprising multiple reading circuits, which are electrically connected to the sensing electrodes and output multiple output signals, respectively.

3. The capacitive sensing array device according to claim 2, wherein each of the reading circuits comprises:
an operational amplifier having a positive input terminal, a negative input terminal and an output terminal, wherein the negative input terminal is electrically connected to the sensing electrode and the positive input terminal is electrically connected to a reference voltage, so that an output of the capacitive sensing array device does not relate to the horizontal parasitic capacitor and the vertical parasitic capacitor;
a tunable capacitor having a first terminal electrically connected to the negative input terminal, and a second terminal electrically connected to the output terminal; and
a reset switch connected to the tunable capacitor in parallel.

4. The capacitive sensing array device according to claim 3, wherein the tunable capacitor comprises:
reference capacitors connected to the negative input terminal and the output terminal in parallel through multiple reference switches, respectively, wherein open-circuited states and short-circuited states of the reference switches are controlled to adjust a capacitance of the tunable capacitor.

5. The capacitive sensing array device according to claim 3, wherein if the reference voltage is Vref, the coupling signal is Vdrive, the sensing capacitor is Cf, and the tunable capacitor has a capacitance of Ch, then a voltage Vout of the output terminal is represented by:
Vout=Vref−(Cf/Ch)×Vdrive.

6. The capacitive sensing array device according to claim 1, further comprising:
a semiconductor substrate, wherein the sensing electrodes, the shielding conductor layers, the coupling signal source, the constant voltage source and the switch modules are formed in the semiconductor substrate;
a package substrate, wherein the semiconductor substrate is disposed on the package substrate;
multiple wires electrically connecting first bonding pads of the package substrate to second bonding pads of the semiconductor substrate; and
a package protection layer covering the semiconductor substrate, the wires, the first bonding pads and the second bonding pads.

7. The capacitive sensing array device according to claim 6, wherein the package protection layer has an exposed surface in contact with the object, and the exposed surface is a flat surface.

8. The capacitive sensing array device according to claim 1, wherein one portion of the shielding conductor layers pertains to one portion of a function block comprising a passive component.

9. The capacitive sensing array device according to claim 1, wherein one portion of the shielding conductor layers pertains to one portion of one or multiple integrated circuit blocks.

10. A capacitive sensing array device with a high frame rate, the capacitive sensing array device comprising:
multiple sensing electrodes separately arranged in an array, wherein a sensing capacitor is formed between each of the sensing electrodes and an object;
a function block group disposed below the sensing electrodes, wherein the function block group comprises multiple function blocks each comprising a wire layer, wherein the wire layers are disposed on multiple planes;
a coupling signal source providing a coupling signal coupled to the object;
a constant voltage source providing a constant voltage to each of the wire layers so that a stable vertical parasitic capacitor is formed between the function block group and each of the sensing electrodes; and
multiple switch modules electrically connected to the sensing electrode and the constant voltage source in a one-to-one manner, wherein when one of the sensing electrodes is selected to perform sensing, the switch modules are configured such that the selected sensing electrode is disconnected from the constant voltage source, and the other sensing electrodes are electrically connected to the constant voltage source, so that a stable horizontal parasitic capacitor is formed between the selected sensing electrode and the other sensing electrodes.

11. The capacitive sensing array device according to claim 10, wherein the function blocks are disposed above active blocks of a substrate, and the active blocks and the function blocks form a plurality of integrated circuit blocks and provide partial or complete sensing circuit functions.

12. The capacitive sensing array device according to claim 11, wherein the wire layers shield the plurality of integrated circuit blocks.

13. The capacitive sensing array device according to claim 10, wherein each of the function blocks is formed by a post-stage metal layer and an inter-metal dielectric layer formed in a semiconductor manufacturing process.

14. The capacitive sensing array device according to claim 10, wherein each of the function blocks further comprises a capacitor, a resistor or an inductor used in an analog circuit.

15. An electronic apparatus, comprising:
a body;
a display mounted on the body, the display displaying a frame;
the capacitive sensing array device according to claim 1, mounted on the body;
a housing mounted on the body and covering the display and the capacitive sensing array device, wherein the capacitive sensing array device senses a pattern of the object via the housing; and
a processor, which is electrically connected to the capacitive sensing array device and the display, processes the pattern of the object and interacts with a user through the display.

16. The electronic apparatus according to claim 15, wherein the capacitive sensing array device further provides a button function, through which the user inputs a control instruction.

17. An electronic apparatus, comprising:
a body;
a display mounted on the body, the display displaying a frame;
the capacitive sensing array device according to claim 10, mounted on the body;
a housing mounted on the body and covering the display and the capacitive sensing array device, wherein the capacitive sensing array device senses a pattern of the object via the housing; and
a processor, which is electrically connected to the capacitive sensing array device and the display, processes the pattern of the object and interacts with a user through the display.

18. The electronic apparatus according to claim 17, wherein the capacitive sensing array device further provides a button function, through which the user inputs a control instruction.
